(19) United States
(12) Patent Application Publication
(10) Pub. No.: US 2025/0273543 A1
(43) Pub. Date: Aug. 28, 2025

(54) SEMICONDUCTOR DEVICE

(71) Applicant: ABLIC Inc., Nagano (JP)

(72) Inventors: Kiyoaki KADOI, Nagano (JP); Takahiro KATO, Nagano (JP)

(73) Assignee: ABLIC Inc., Nagano (JP)

(21) Appl. No.: 19/008,597

(22) Filed: Jan. 2, 2025

(30) Foreign Application Priority Data
Feb. 27, 2024 (JP) 2024-027713
Sep. 17, 2024 (JP) 2024-160019

(51) Int. Cl. H01L 23/495; H01L 23/31

(52) U.S. Cl. CPC H01L 23/49548; H01L 23/3121; H01L 23/49582

(57) ABSTRACT

A semiconductor device includes a semiconductor chip, a plurality of leads arranged apart from each other around the semiconductor chip in a plan view and extending from the semiconductor chip side, and an encapsulating resin forming an outer shape such that at least lower surfaces and end faces of the plurality of leads are respectively exposed, and the lead includes a lead main body portion positioned on the semiconductor chip side, having a first end face formed in an extending direction, and having a chamfering portion at a corner portion between a lower surface and the first end face, and a lead outer end portion extending from the first end face, having an upper surface that is coplanar with the lead main body portion, being thinner than the lead main body portion, and on which a second end face is formed.

### CROSS-REFERENCE TO RELATED APPLICATION

This application claims the priority benefits of Japanese application no. 2024-027713, filed on Feb. 27, 2024, and Japanese application no. 2024-160019, filed on Sep. 17, 2024. The entirety of the above-mentioned patent application is hereby incorporated by reference herein and made a part of this specification.

### BACKGROUND

### Technical Field

The present invention relates to a semiconductor device.

### Description of Related Art

As electronic machines such as mobile phones and mobile machines become more functional, there is an increasing demand for miniaturization and thinning of semiconductor devices used in such electronic machines.

A common package for a semiconductor device formed by molding epoxy resin includes a structure in which a semiconductor chip is mounted on a die pad, which is part of a lead frame, and covered with epoxy resin to form an outer shape. One form of such a small package structure is a non-lead type DFN (Dual Flat Nonleaded) package.

DFN packages are generally manufactured by singulating a resin-encapsulated lead frame with exposed lower surfaces of the leads through cutting with a dicing device. As a result, DEN packages have a structure where the lead end faces are exposed from the cut side surfaces of the encapsulating resin, and the lead end faces are flush with the encapsulating resin. As mentioned above, since DFN packages are singulated by cutting with a dicing device,

the lead end faces expose the lead material as is. Thus, when bonding the leads to a mounting substrate with solder or the like, it is difficult to form sufficient fillets on the lead end faces if the lead material has low solder wettability. In the case of bonding only the lower surface of the lead with a plating layer to the mounting substrate, the bonding area decreases, which may result in reduced bonding strength between the leads and the mounting substrate.

To suppress the decrease in bonding strength between the leads and the mounting substrate, for example, the invention described in Patent Document 1 (Patent Document 1: Japanese Patent Application Laid-Open (JP-A) No. 2016-219520) discloses a semiconductor device in which a plating layer is formed in a concave portion formed at the corner portion between the lower surface and end face of the lead.

One aspect of the present invention provides a semiconductor device including a lead that may ensure bonding reliability with a mounting substrate even in a non-lead type package.

### SUMMARY

A semiconductor device according to one embodiment of the present invention includes:

a semiconductor chip;

a plurality of leads arranged apart from each other around the semiconductor chip in a plan view and extending from the semiconductor chip side; and

an encapsulating resin forming an outer shape such that at least lower surfaces and end faces of the plurality of leads are respectively exposed.

The lead includes:

a lead main body portion positioned on the semiconductor chip side, having a first end face formed in an extending direction, and having a chamfering portion at a corner portion between a lower surface and the first end face; and

a lead outer end portion extending from the first end face, having an upper surface that is coplanar with the lead main body portion, being thinner than the lead main body portion, and on which a second end face is formed to be exposed from a side surface of the encapsulating resin.

A lower surface of the lead main body portion, the first end face, the chamfering portion, and a lower surface of the lead outer end portion are covered with a metal film.

### BRIEF DESCRIPTION OF THE DRAWINGS

FIG. 1 is a schematic top view (perspective view) of the semiconductor device according to the first embodiment of the present invention.

FIG. 2A is a schematic side view (perspective view) of the semiconductor device illustrated in FIG. 1.

FIG. 2B is an enlarged view of part A in FIG. 2A.

FIG. 3 is a diagram illustrating the manufacturing process of the semiconductor device according to the first embodiment of the present invention.

FIG. 4 is a diagram illustrating the manufacturing process of the semiconductor device according to the first embodiment of the present invention, continuing from FIG. 3.

FIG. 5 is a diagram illustrating the manufacturing process of the semiconductor device according to the first embodiment of the present invention, continuing from FIG. 4.

FIG. 6A is a schematic side view (perspective view) illustrating the semiconductor device in a modification example of the first embodiment of the present invention.

FIG. 6B is an enlarged view of part B in FIG. 6A.

FIG. 7A is a schematic side view (perspective view) illustrating the semiconductor device according to the second embodiment of the present invention.

FIG. 7B is an enlarged view of part C in FIG. 7A.

### DESCRIPTION OF THE EMBODIMENTS

The embodiments for implementing the present invention are described in detail below

with reference to the drawings. In addition, in the drawings, the same component parts may be given the same signs, and redundant explanations may be omitted.

Further, the X-axis, Y-axis and Z-axis shown in the drawings are assumed to be orthogonal to each other. The Z-axis direction may be referred to as “height direction” or “thickness direction.” The +Z-axis direction may be referred to as “upward”, and the −Z-axis direction may be referred to as “downward”. The surface on the +Z direction side of each component may be referred to as the “front surface” or “upper surface”, and the surface on the −Z direction side may be referred to as the “back surface” or “lower surface”. “Plan view” refers to viewing each component from the +Z direction side toward the −Z direction side. “Side view” refers to viewing each component transparently from the +Y direction side toward the −Y direction side.

Further, the drawings are schematic, and the width, depth, thickness ratio, etc. are not as shown. The quantity, position, shape, structure, size, etc. of each component are not limited to the embodiments shown below, but may be any quantity, position, shape, structure, size, etc. that is desirable in implementing the present invention.

### First Embodiment

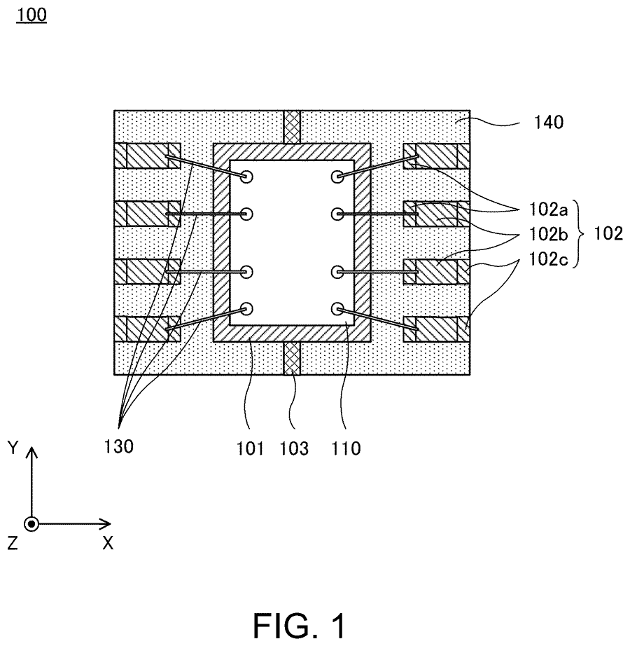

FIG. 1 is a schematic top view (perspective view) of the semiconductor device according to the first embodiment of the present invention. As illustrated in FIG. 1, the semiconductor device 100 according to the first embodiment of the present invention includes a semiconductor chip 110, a plurality of leads 102, and an encapsulating resin 140.

The semiconductor chip 110 is a semiconductor chip for enabling the function of the semiconductor device 100, and is mounted on the upper surface of the die pad 101. The plurality of leads 102 are arranged at a constant distance apart from each other on two opposing sides in the +X direction and-X direction of the die pad 101 in plan view. Each of the plurality of leads 102 includes a lead tip end portion 102a, a lead main body portion 102b, and a lead outer end portion 102c.

A plurality of electrode pads (not shown) formed on the upper surface of the semiconductor chip 110 are electrically connected to the upper surfaces of the lead tip end portions 102a and the lead main body portions 102b of the plurality of leads 102 by conductive wires 130. For this reason, the upper surfaces of the lead tip end portions 102a and the lead main body portions 102b are formed on the same smooth surface. Thus, a wide area may be secured on the upper surface of the lead 102 for performing a second bond of the conductive wire 130. This allows for securing the bonding area for wire bonding and may suppress the decrease in connection strength. The conductive wire 130 is, for example, a gold wire or a copper wire.

The hanging portions 103 extend from two sides of the die pad 101 in the +Y direction and −Y direction. It is noted that in this embodiment, the die pad 101, the plurality of leads 102, and the hanging portions 103 are formed of the same copper alloy material and have an integrated lead frame structure. FIG. 1 illustrates one combination that forms one semiconductor device. It is ultimately divided into individual semiconductor devices.

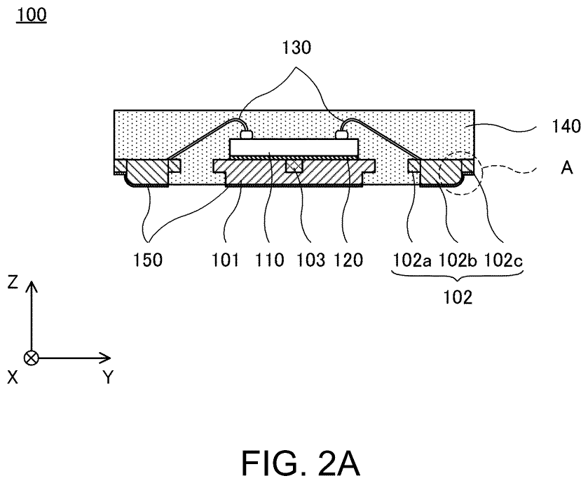

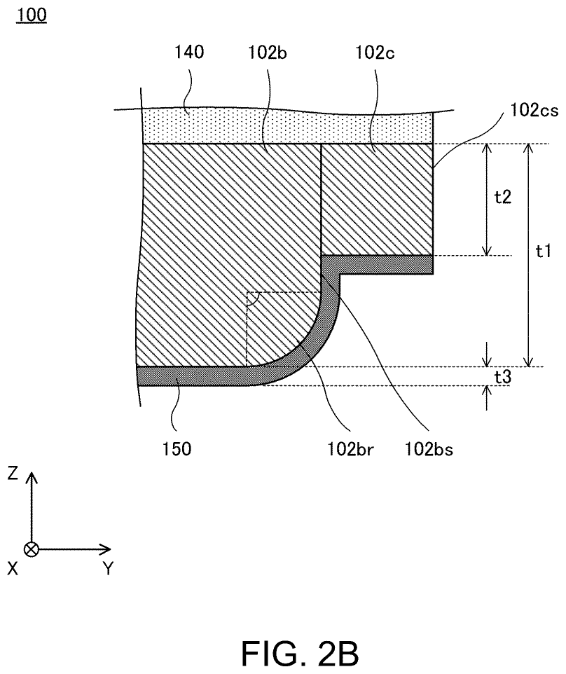

FIG. 2A is a schematic side view (perspective view) of the semiconductor device illustrated in FIG. 1. As shown in FIG. 2A, the semiconductor chip 110 is mounted on the upper surface of the die pad 101 with a conductive adhesive 120. A metal film 150 is formed on the lower surface of the die pad 101 and is exposed from the encapsulating resin 140 to improve the heat dissipation of the semiconductor chip 110. The periphery of the lower surface of the die pad 101 is formed to be thin. This creates a structure where the encapsulating resin 140 enters the lower portion around the die pad 101, preventing the die pad 101 from falling out of the encapsulating resin 140.

FIG. 2B is an enlarged view of part A in FIG. 2A. As shown in FIG. 2B, the plurality of leads 102 include a lead tip end portion 102a, a lead main body portion 102b, and a lead outer end portion 102c.

The upper surface of the lead tip end portion 102a is on the same plane as the upper surface of the lead main body portion 102b, and the thickness of the lead tip end portion 102a is formed to be thinner than the thickness of the lead main body portion 102b. This creates a structure where the encapsulating resin 140 enters the lower surface of the lead tip end portion 102a, preventing the lead 102 from falling out of the encapsulating resin 140.

The lead main body portion 102b has a chamfering portion 102br formed at the corner portion between its lower surface and the first end face 102bs in the extending direction. Chamfering means removing the corner portion, and in the first embodiment, it is done as rounding processing to add roundness to the corner portion. However, as described in a modification example later, one or more angled surfaces may be provided at the corner portion.

In conventional DFN packages where a concave portion is formed on the lower surface and end face of the lead, it is common to have a corner portion between the lower surface of the lead and the concave portion. In such a structure, in response to conducting a reliability test that repeats temperature changes between high and low temperatures, stress generated due to differences in thermal expansion coefficients among the lead, encapsulating resin, and mounting substrate concentrates at the corner portion. This stress may cause cracks in the solder at the bonding portion between the corner portion and the mounting substrate. Thus, compared to the leads of conventional DFN package semiconductor devices mentioned above, this semiconductor device 100 may suppress the concentration of stress.

The second end face 102cs of the lead outer end portion 102c is exposed from the side surface of the encapsulating resin. The upper surface of the lead outer end portion 102c is on the same plane as the upper surface of the lead main body portion 102b, and the thickness t2 of the lead outer end portion 102c is formed to be thinner than the thickness t1 of the lead main body portion 102b. By making the thickness t2 of the lead outer end portion 102c ½ or less of the thickness t1 of the lead main body portion 102b, it becomes easier to form a sufficient fillet on the end face of the lead.

The metal film 150 is formed on the lower surface of the die pad 101, and is continuously formed on the lower surface of the lead main body portion 102b, the first end face 102bs in the extending direction, the chamfering portion 102br, and the lower surface of the lead outer end portion 102c of a plurality of leads 102. The metal film 150 formed on a plurality of leads 102 is exposed from the encapsulating resin and is used as an external terminal of the semiconductor device. The metal film 150 on the chamfering portion 102br maintains its rounded shape.

The thickness t3 of the metal film 150 is 10 μm or more and 50 μm or less, and it protrudes slightly from the encapsulating resin 140. The thickness of the metal film 150 may be changed as appropriate.

The material of the metal film 150 may be any material with good solder wettability, for example, lead, bismuth, tin, copper, silver, palladium, gold, or alloys of these may be mentioned.

As a result, compared to a lead structure without a chamfering portion 102br, this semiconductor device 100 allows solder to climb more easily, making it easier to form sufficient fillets on the end face of the lead.

The manufacturing process of the semiconductor device 100 is described with reference

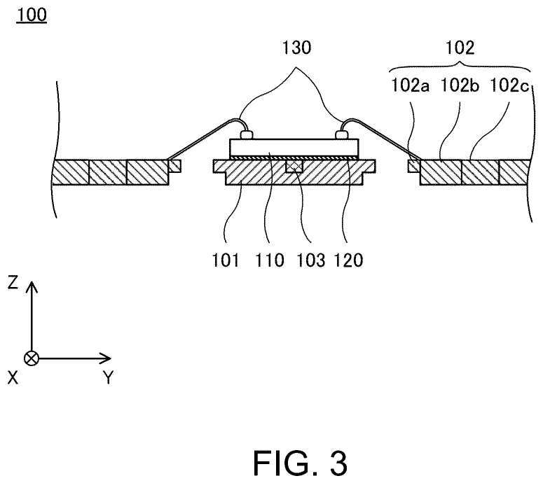

to FIG. 3 to FIG. 5.

As illustrated in FIG. 3, the semiconductor chip 110 is fixed to the upper surface of the die pad 101 with conductive adhesive 120. Subsequently, a plurality of electrode pads (not shown) formed on the upper surface of the semiconductor chip 110 are electrically connected to the upper surfaces of a plurality of leads 102 with conductive wires 130. In this embodiment, the die pad 101 and the plurality of leads 102 are formed of the same copper alloy material and possess an integrated lead frame structure. In this state, the lead outer end portions 102c of the plurality of leads 102 have the same thickness as the lead main body portions 102b.

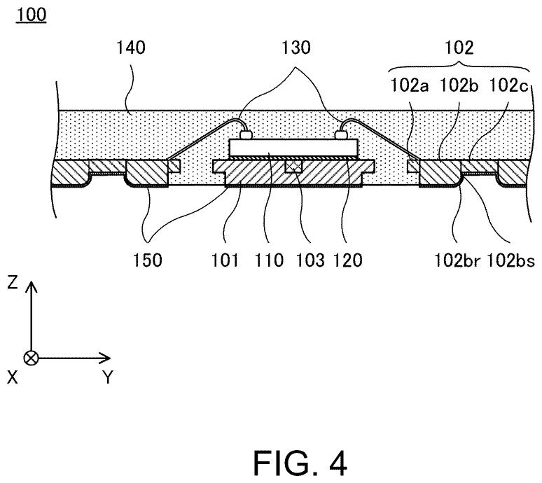

Next, as illustrated in FIG. 4, the lead frame is held between two molds (not shown), and encapsulating resin is injected into the interior of the molds and solidified to encapsulate. The lower surface of the die pad 101, the lower surface of the lead main body portion 102b, and the lower surface of the lead outer end portion 102c are exposed from the encapsulating resin 140.

Subsequently, using a dicing device, a first cutting process is performed to form the lead outer end portion 102c to a predetermined thickness. The first cutting process cuts the thickness of the lead outer end portion 102c to a thickness of 5% to 80% of the thickness of the lead main body portion 102b. In this state, the first end face 102bs of the lead main body portion 102b is formed and exposed from the encapsulating resin 140.

Next, by etching using a chemical solution, a chamfering portion 102br is formed at the corner portion between the lower surface of the lead main body portion 102b and the first end face 102bs. At this time, the lower surface of the lead main body portion 102b may be recessed in the +Z direction relative to the lower surface of the encapsulating resin 140.

In the first cutting process, burrs of copper alloy, which is the material of the lead 102, may occur on the first end face 102bs of the lead main body portion 102b and the lower surface of the lead main body portion 102b, and these burrs may cause short circuits between adjacent leads. Thus, by etching using a chemical solution to form the chamfering portion 102br, it is possible to remove these burrs and suppress the occurrence of short circuits between leads. Examples of the chemical solution include sulfuric acid peroxide and hydrochloric acid peroxide.

Subsequently, a metal film 150 is formed on the lower surface of the die pad 101, the lower surface of the lead main body portion 102b, the first end face 102bs, and the lower surface of the lead outer end portion 102c exposed from the encapsulating resin 140 by electrolytic plating method.

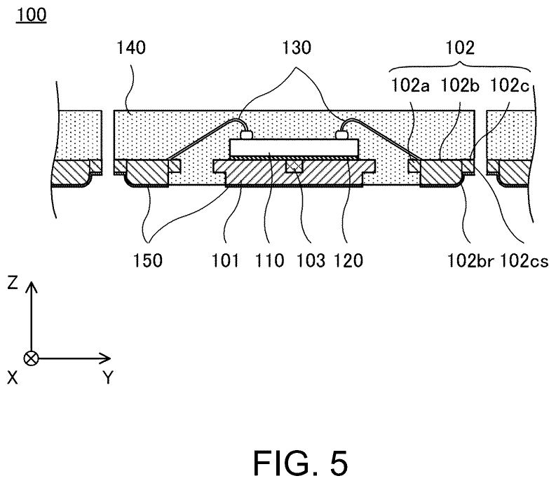

Next, as shown in FIG. 5, the semiconductor device 100 is manufactured by cutting and singulating the lead outer end portion 102c and the encapsulating resin 140 at predetermined positions by a second cutting process using a dicing device. In this case, the blade width of the dicing device used in the second cutting process is narrower than the blade width used in the first cutting process. As a result, the lead outer end portion 102c of each individual semiconductor device 100 is formed, and the second end face 102cs of the lead outer end portion 102c is formed on the side surface of the encapsulating resin 140.

In this manner, in the semiconductor device 100 of this embodiment, the chamfering portion 102br is formed at the corner portion between the lower surface of the lead main body portion 102b and the first end face 102bs in the extending direction, and the metal film 150 with good solder wettability is formed on the chamfering portion 102br.

As a result, in the semiconductor device 100, the stress generated due to the difference in thermal expansion coefficient does not concentrate at the corner portion, and furthermore, solder may climb up more easily, thereby ensuring bonding reliability with the mounting substrate even with a non-lead type package.

### Modification Example of the First Embodiment

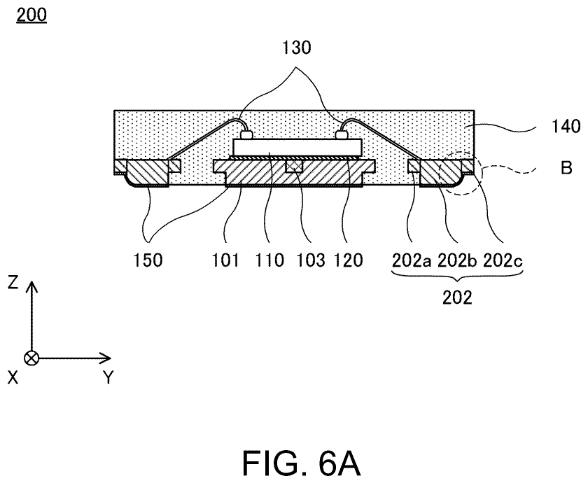

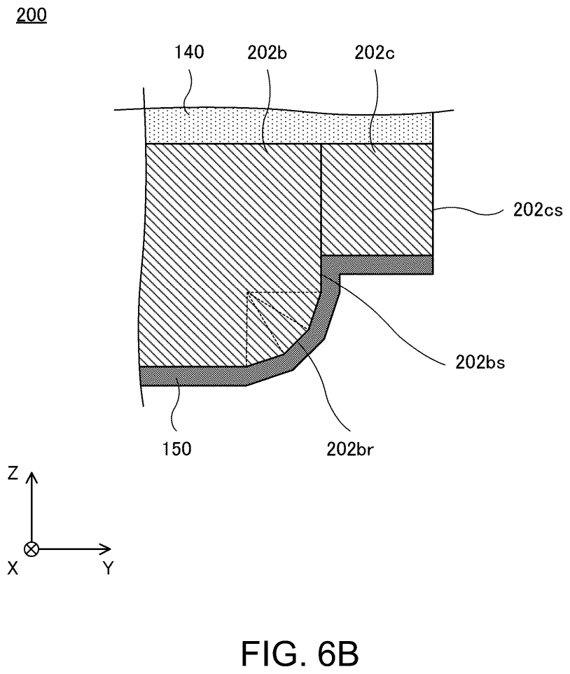

FIG. 6A is a schematic side view (perspective view) illustrating the semiconductor device in a modification example of the first embodiment of the present invention, and FIG. 6B is an enlarged view of part B in FIG. 6A.

As shown in FIG. 6A and FIG. 6B, the semiconductor device 200 according to the modification example of the first embodiment of the present invention is similar to the first embodiment of the present invention, except that the rounded shape in the chamfering portion 102br is composed of three surfaces with inclinations. In the configuration of FIG. 6A and FIG. 6B as well, in the case of connecting the lead to the mounting substrate, cracks are less likely to occur in the solder at the bonding portion between the chamfering portion and the mounting substrate, and it is possible to improve the climbing of solder from the lower surface of the lead main body portion 202b to the lower surface of the lead outer end portion 202c. Thus, the modification example of the first embodiment of the present invention may ensure bonding reliability with the mounting substrate even with a non-lead type package.

### Second Embodiment

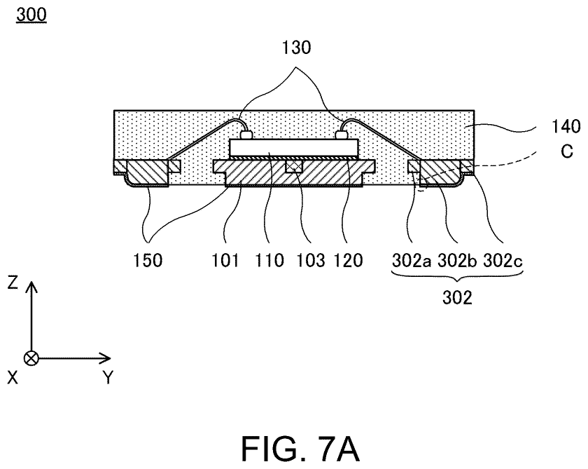

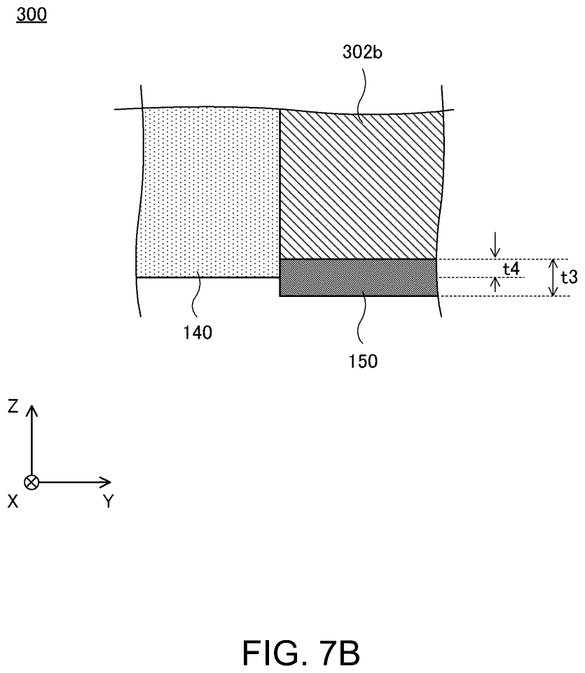

FIG. 7A is a schematic side view (perspective view) illustrating the semiconductor device according to the second embodiment of the present invention, and FIG. 7B is an enlarged view of part C in FIG. 7A.

As shown in FIG. 7A and FIG. 7B, the lower surface of the lead main body portion 302b is formed at a position above the lower surface of the encapsulating resin 140 with a height t4. The height t4 is not particularly limited, but for example, it is 1 μm or more and 10 μm or less. Other aspects are similar to the semiconductor device 100.

In DEN packages, it is common for the lower surface of the lead and the lower surface of the encapsulating resin to be on the same plane. In such a structure, in response to a metal film being formed on the lower surface of the lead, stress generated due to differences in thermal expansion coefficients between the lead, encapsulating resin, and mounting substrate concentrates at the interface between the lead and the metal film. This stress may cause cracks to occur at the interface between the lead and the metal film.

In the semiconductor device 300 of the second embodiment, the lower surface 102b of the lead main body portion 302b is formed at a position above the lower surface 140b of the encapsulating resin 140. This structure suppresses the concentration of stress at the interface between the lead main body portion 302b and the metal film 150, which is generated due to differences in thermal expansion coefficients between the lead, encapsulating resin, and mounting substrate, thereby suppressing the occurrence of cracks at the interface between the lead main body portion 302b and the metal film 150. Thus, the semiconductor device 300 may ensure bonding reliability with the mounting substrate even in a non-lead type package.

The present invention has been described with respect to one embodiment, but the present invention is not limited to this embodiment and includes designs within the scope that do not depart from the gist of the present invention.

For example, in this embodiment, the package of the semiconductor device is described as a DFN package, but it is not limited to this and may be other packages. The semiconductor chip is mounted on the upper surface of the die pad by adhering it with a conductive adhesive or the like, but the present invention is not limited to this and the semiconductor chip may be mounted on a resin film. The die pad may not exist. Further, the embodiment uses conductive wires for electrical connection between the lead and the semiconductor chip, but it may also be in a flip chip configuration. In the case of this flip chip configuration, the die pad no longer exists, and bumps formed on the upper surface of the semiconductor chip may be used for electrical connection between the lead and the semiconductor chip.

Further, the material of the lead frame is described as copper alloy, but it is not limited to this and may be other materials. The method of forming the metal film is described as electrolytic plating method, but electroless plating method may also be used. In the modification example, the chamfering portion is composed of three surfaces, but it is not limited to this and may be composed of one or more surfaces.

What is claimed is:

1. A semiconductor device, comprising:
a semiconductor chip;
a plurality of leads arranged apart from each other around the semiconductor chip in a plan view and extending from the semiconductor chip side; and
an encapsulating resin forming an outer shape such that at least lower surfaces and end faces of the plurality of leads are respectively exposed,
wherein the lead comprises:
a lead main body portion positioned on the semiconductor chip side, having a first end face formed in an extending direction, and having a chamfering portion at a corner portion between a lower surface and the first end face; and
a lead outer end portion extending from the first end face, having an upper surface that is coplanar with the lead main body portion, being thinner than the lead main body portion, and on which a second end face is formed, and
a lower surface of the lead main body portion, the first end face, the chamfering portion, and a lower surface of the lead outer end portion are covered with a metal film.

2. The semiconductor device according to claim 1, wherein the chamfering portion is subjected to rounding processing.

3. The semiconductor device according to claim 1, wherein the chamfering portion is composed of a surface having an inclination.

4. The semiconductor device according to claim 1, wherein a thickness of the lead outer end portion is ½ or less of a thickness of the lead main body portion.

5. The semiconductor device according to claim 1, wherein a lower surface of the lead main body portion is formed at a position above a lower surface of the encapsulating resin.

6. The semiconductor device according to claim 2, wherein a lower surface of the lead main body portion is formed at a position above a lower surface of the encapsulating resin.

7. The semiconductor device according to claim 3, wherein a lower surface of the lead main body portion is formed at a position above a lower surface of the encapsulating resin.

8. The semiconductor device according to claim 4, wherein a lower surface of the lead main body portion is formed at a position above a lower surface of the encapsulating resin.
